(19) United States
(12) Patent Application Publication
(10) Pub. No.: US 2022/0149306 A1
(43) Pub. Date: May 12, 2022

(54) LIGHT EMITTING ELEMENT AND DISPLAY DEVICE INCLUDING THE SAME

(71) Applicant: Samsung Display Co., Ltd., Yongin-si (KR)

(72) Inventors: JAE HONG PARK, Seoul (KR); JAEHOON KIM, Seoul (KR); HYUNMI DOH, Seoul (KR); MYOUNGJIN PARK, Hwaseong-si (KR)

(21) Appl. No.: 17/450,827

(22) Filed: Oct. 13, 2021

(30) Foreign Application Priority Data
Nov. 9, 2020 (KR) 10-2020-0148904

(51) Int. Cl. H01L 51/50; H01L 27/32

(52) U.S. Cl. CPC H01L 51/502; H01L 27/322; H01L 27/3246; H01L 51/5092; H01L 51/5072; H01L 51/5088; H01L 51/5056

(57) ABSTRACT

Provided is a light emitting element and a display device including a first electrode, a hole transport region on the first electrode, an emission layer on the hole transport region and including quantum dots, an electron transport region on the emission layer, and a second electrode on the electron transport region, wherein at least one selected from the hole transport region and the electron transport region includes an antioxidant, thereby exhibiting increased luminous efficiency.

### CROSS-REFERENCE TO RELATED APPLICATIONS

This application claims priority to and the benefit of Korean Patent Application No. 10-2020-0148904, filed on Nov. 9, 2020, in the Korean Intellectual Property Office, the entire contents of which are hereby incorporated by reference.

### BACKGROUND

### 1. Field

Embodiments of the present disclosure herein relate to a light emitting element and a display device including the same, and, for example, to a light emitting element having increased luminous efficiency and service life and a display device including the same.

### 2. Description of Related Art

Various types of display devices used for multimedia devices such as a television set, a mobile phone, a tablet computer, a navigation system, and a game console are being developed. In such display devices, a so-called self-luminescent display element is used which accomplishes display by causing an organic compound-containing light emitting material to emit light.

In addition, the development of a light emitting element using quantum dots as a light emitting material is underway as an effort to enhance the color reproducibility of display devices, and there is a demand for increasing the reliability and service life of the light emitting element using the quantum dots.

The present disclosure provides a light emitting element having increased luminous efficiency and service life.

The present disclosure also provides a display device including a light emitting element having increased luminous efficiency and service life.

### SUMMARY

An embodiment of the present disclosure provides a light emitting element including a first electrode, a hole transport region on the first electrode, an emission layer on the hole transport region and including quantum dots, an electron transport region on the emission layer, and a second electrode on the electron transport region, wherein at least one selected from the hole transport region and the electron transport region includes an antioxidant.

In an embodiment, the antioxidant may include a phenolic compound and/or an amine-based compound.

In an embodiment, the electron transport region may include an electron transport layer on the emission layer and an electron injection layer on the electron transport layer, wherein at least one selected from the electron transport layer and the electron injection layer may include the antioxidant.

In an embodiment, the electron transport layer may include zinc oxide and the antioxidant, and the electron transport layer may be directly on the emission layer.

In an embodiment, the hole transport region may include a hole injection layer on the first electrode and a hole transport layer on the hole injection layer, wherein at least one selected from the hole injection layer and the hole transport layer may include the antioxidant.

In an embodiment, the emission layer may include the antioxidant, and the antioxidant may be included in an amount of about 0.1 mass % to about 10 mass % with respect to a total weight of the quantum dots.

In an embodiment, the light emitting element may further include a first anti-oxidation layer between the electron transport region and the emission layer and including the antioxidant.

In an embodiment, the light emitting element may further include a second anti-oxidation layer between the hole transport region and the emission layer and including the antioxidant.

In an embodiment of the present disclosure, a light emitting element includes a first electrode, a hole transport region on the first electrode, an emission layer on the hole transport region and including quantum dots, an electron transport region on the emission layer, a second electrode on the electron transport region, and an anti-oxidation layer on the hole transport region, wherein the anti-oxidation layer includes an antioxidant.

In an embodiment, the electron transport region may include zinc oxide, the anti-oxidation layer may be between the electron transport region and the emission layer, and the antioxidant may include an amine-based compound.

In an embodiment, the anti-oxidation layer may be between the hole transport region and the emission layer.

In an embodiment, the anti-oxidation layer may be between the electron transport region and the second electrode.

In an embodiment, the anti-oxidation layer may be on the second electrode.

In an embodiment of the present disclosure, a display device includes a display panel including a base layer and a plurality of light emitting elements on the base layer, and an optical member on the display panel, wherein the plurality of light emitting elements each include a first electrode, a hole transport region on the first electrode, an emission layer on the hole transport region and including quantum dots, an electron transport region on the emission layer, and a second electrode on the electron transport region, at least one selected from the hole transport region and the electron transport region including an antioxidant.

In an embodiment, the plurality of light emitting elements may include a first light emitting element including a first quantum dot to emit a first light, a second light emitting element including a second quantum dot to emit a second light having a longer wavelength than the first light, and a third light emitting element including a third quantum dot to emit a third light having a longer wavelength than the first light and the second light.

In an embodiment, the optical member may include a color filter layer, wherein the color filter layer may include a first filter to transmit the first light, a second filter to transmit the second light, and a third filter to transmit the third light.

In an embodiment, the display device may further include a first anti-oxidation layer between the electron transport region and the emission layer and including the antioxidant, or a second anti-oxidation layer between the hole transport region and the emission layer and including the antioxidant.

In an embodiment, the electron transport region may include zinc oxide, and the antioxidant may include an amine-based compound.

In an embodiment, the display panel may further include a pixel defining film on the base layer and having a plurality of openings respectively corresponding to the plurality of light emitting elements defined therein, and a fifth anti-oxidation layer on the pixel defining film and including the antioxidant.

In an embodiment, the display panel may further include a pixel defining film on the base layer and having a plurality of openings respectively corresponding to the plurality of light emitting elements defined therein, wherein the pixel defining film may include the antioxidant.

### BRIEF DESCRIPTION OF THE DRAWINGS

The accompanying drawings are included to provide a further understanding of the subject matter of the present disclosure, and are incorporated in and constitute a part of this specification. The drawings illustrate embodiments of the present disclosure and, together with the description, serve to explain principles of the present disclosure. In the drawings:

FIG. 1 is a combined perspective view of an electronic device according to an embodiment of the present disclosure;

FIG. 2 is an exploded perspective view of an electronic device according to an embodiment of the present disclosure;

FIG. 3 is a cross-sectional view of a display device corresponding to line I-I′ of FIG. 2 according to an embodiment of the present disclosure;

FIGS. 4 to 14 are cross-sectional views of a light emitting element according to an embodiment of the present disclosure;

FIG. 15 is a plan view of a display device according to an embodiment of the present disclosure; and

FIGS. 16 and 17 are cross-sectional views of a display device according to an embodiment of the present disclosure.

### DETAILED DESCRIPTION

In the present description, when an element (or a region, a layer, a portion, etc.) is referred to as being “on,” “connected to,” or “coupled to” another element, it means that the element may be directly on/connected to/coupled to the other element, or that a third element may be therebetween.

In the present description, “directly on” may indicate that there is no layer, film, region, plate or the like added between a portion of a layer, a film, a region, a plate or the like and other portions. For example, “directly on” may indicate a layer or member is on another layer member without additional members such as an adhesive member between the two layers or two members.

Like reference numerals refer to like elements. Also, in the drawings, the thickness, the ratio, and the dimensions of elements may be exaggerated for an effective description of technical contents.

The term “and/or,” includes all combinations of one or more of which associated configurations may define.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the spirit and scope of the present disclosure. The terms of a singular form may include plural forms unless the context clearly indicates otherwise.

In addition, terms such as “below,” “lower,” “above,” “upper,” and the like are used to describe the relationship of the configurations shown in the drawings. The terms are used as a relative concept and are described with reference to the direction indicated in the drawings.

Unless otherwise defined, all terms (including technical and scientific terms) used herein have the same meaning as commonly understood by one of ordinary skill in the art to which the present disclosure pertains. It is also to be understood that terms defined in commonly used dictionaries should be interpreted as having meanings consistent with the meanings in the context of the related art, and are expressly defined herein unless they are interpreted in an ideal or overly formal sense.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

Hereinafter, a light emitting element according to an embodiment of the present disclosure and a display device including the same will be described with reference to the accompanying drawings.

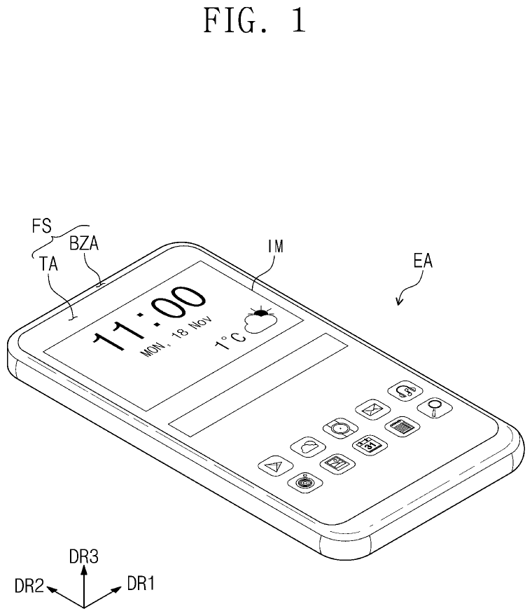

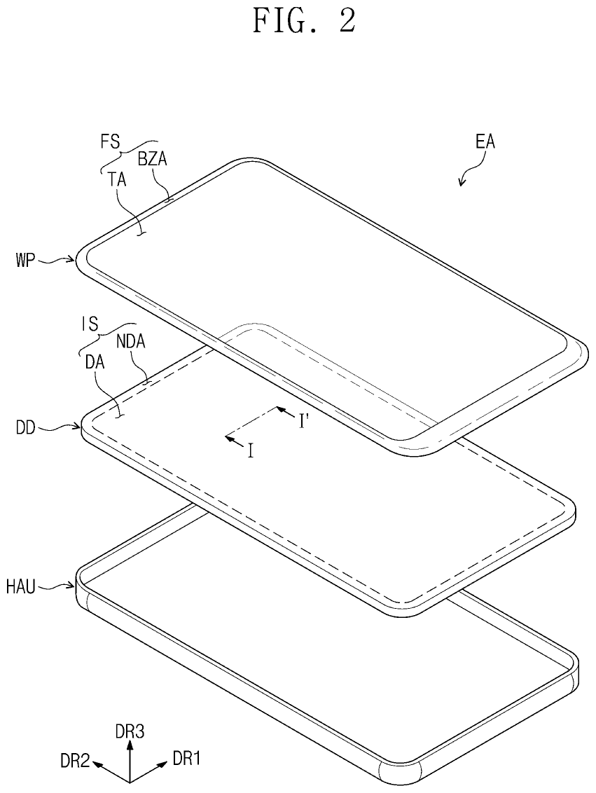

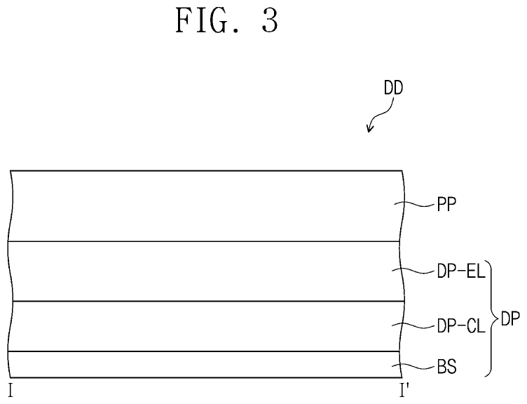

FIG. 1 is a perspective view illustrating an electronic device EA of an embodiment. FIG. 2 is an exploded perspective view of an electronic device EA of an embodiment. FIG. 3 is a cross-sectional view of a display device DD according to an embodiment.

In an embodiment, the electronic device EA may be a large-sized electronic device such as a television set, a monitor, or an outdoor billboard. In addition, the electronic device EA may be a small- and/or medium-sized electronic device such as a personal computer, a laptop computer, a personal digital terminal, a car navigation unit, a game console, a smartphone, a tablet, and/or a camera. In addition, these are merely presented as an example, and thus it may be adopted for other electronic devices without departing from the spirit and scope of the present disclosure. In the present embodiment, a smartphone is illustrated as the electronic device EA as an example, but the present disclosure is not limited thereto.

The electronic device EA may include a display device DD and a housing HAU. The display device DD may display an image IM through a display surface IS. FIG. 1 illustrates that the display surface IS is parallel (e.g., substantially parallel) to a plane defined by a first direction DR1 and a second direction DR2 crossing the first direction DR1. However, this is presented as an example, and in another embodiment, the display surface IS of the display device DD may have a curved shape.

Among the normal directions of display surface IS, that is, the thickness directions of the display device DD, a direction in which the image IM is displayed is indicated by a third direction DR3. A front surface (or an upper surface) and a rear surface (or a lower surface) of respective members may be defined by the third direction DR3.

A fourth direction DR4 (see FIG. 15) may be a direction between the first direction DR1 and the second direction DR2. The fourth direction DR4 may be positioned on a plane parallel (e.g., substantially parallel) to the plane defined by the first direction DR1 and the second direction DR2. In one or more embodiments, the directions indicated by the first to fourth directions DR1, DR2, DR3 and DR4 are relative concepts, and may thus be changed to other directions.

The display surface IS on which the image IM is displayed in the electronic device EA may correspond to a front surface of the display device DD and a front surface FS of a window WP. Hereinafter, like reference numerals will be given for the display surface and the front surface of the electronic device EA, and the front surface of the window WP. The image IM may include a still image as well as a dynamic image. In one or more embodiments, the electronic device EA may include a foldable display device having a folding area and a non-folding area, or a bending display device having at least one bending portion.

The housing HAU may accommodate the display device DD. The housing HAU may cover the display device DD such that an upper surface, which is the display surface IS of the display device DD, is exposed. The housing HAU may cover a side surface and a bottom surface of the display device DD, and expose a whole upper surface. However, the present disclosure is not limited thereto, and the housing HAU may cover a portion of the upper surface as well as the side and bottom surfaces of the display device DD.

In the electronic device EA of an embodiment, the window WP may include an optically transparent insulating material (e.g., an optically transparent electrically insulating material). The window WP may include a transmission area TA and a bezel area BZA. The front surface FS of the window WP including the transmission area TA and the bezel area BZA corresponds to the front surface FS of the electronic device EA. Users may view images provided through the transmission area TA corresponding to the front surface FS of the electronic device EA.

In FIGS. 1 and 2, the transmission area TA is shown in a rectangular shape with vertices rounded. However, this is presented as an example, and the transmission area TA may have various suitable shapes and is not limited to any one embodiment.

The transmission area TA may be an optically transparent area. The bezel area BZA may be an area having a relatively lower light transmittance than the transmission area TA. The bezel area BZA may have a set or predetermined color. The bezel area BZA may be adjacent to the transmission area TA and may surround the transmission area TA. The bezel area BZA may define the shape of the transmission area TA. However, the present disclosure is not limited to the one illustrated, the bezel area BZA may be adjacent to only one side of the transmission area TA, and a portion thereof may be omitted.

The display device DD may be below the window WP. In the present description, the term “below” may indicate a direction opposite to the direction in which the display device DD provides an image.

In an embodiment, the display device DD may be substantially configured to generate an image IM. The image IM generated in the display device DD is displayed on the display surface IS, and is viewed by users through the transmission area TA from the outside. The display device DD includes a display area DA and a non-display area NDA. The display area DA may be an area activated according to electrical signals. The non-display area NDA may be an area covered by the bezel area BZA. The non-display area NDA is adjacent to the display area DA. The non-display area NDA may surround the display area DA.

The display device DD may include a display panel DP and an optical member PP on the display panel DP. The display panel DP may include a display element layer DP-EL. The display element layer DP-EL includes a light emitting element ED.

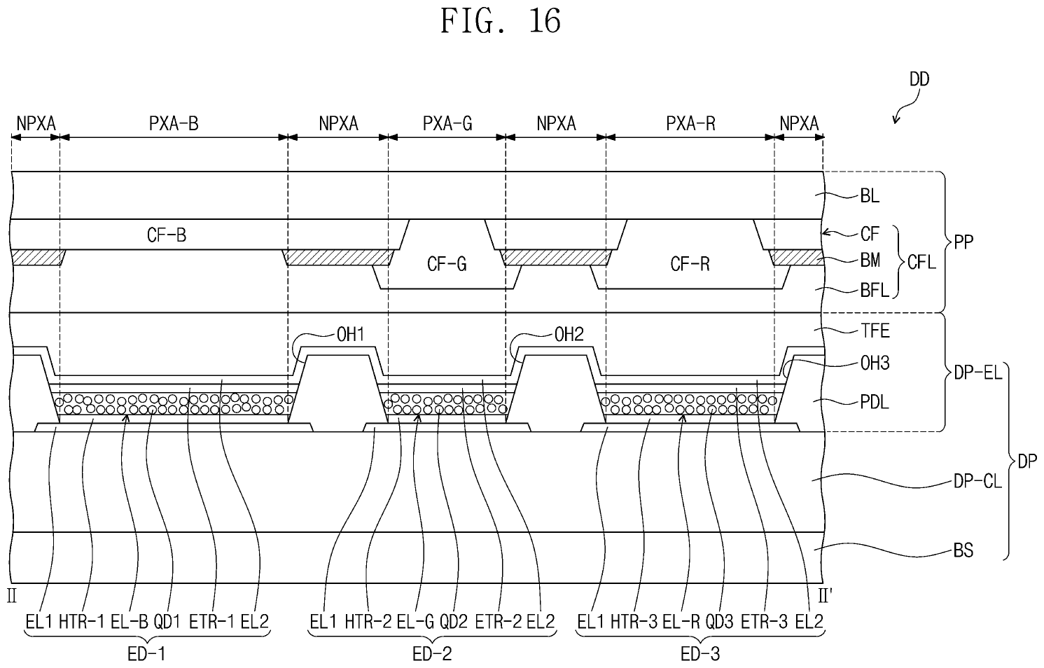

The display device DD may include a plurality of light emitting elements ED-1, ED-2, and ED-3 (see FIG. 16). The optical member PP may be on the display panel DP to control reflected light in the display panel DP due to external light. The optical member PP may include, for example, a polarizing layer, and/or a color filter layer.

In the display device DD of an embodiment, the display panel DP may be a light emitting display panel. For example, the display panel DP may be a quantum dot light emitting display panel including a quantum dot light emitting element. However, the present disclosure is not limited thereto, and the display panel DP may be an organic light emitting display panel including an organic electroluminescence element.

The display panel DP may include a base substrate BS, a circuit layer DP-CL on the base substrate BS, and a display element layer DP-EL on the circuit layer DP-CL.

The base substrate BS may be a member that provides a base surface in which the display element layer DP-EL is located. The base substrate BS may be a glass substrate, a metal substrate, a plastic substrate, etc. However, the present disclosure is not limited thereto, and the base substrate BS may be an inorganic layer, an organic layer or a composite material layer including an inorganic material and an organic material. The base substrate BS may be a flexible substrate that may be readily bent and/or folded.

In an embodiment, the circuit layer DP-CL may be on the base substrate BS, and the circuit layer DP-CL may include a plurality of transistors. For example, the circuit layer DP-CL may include a switching transistor and a driving transistor for driving a light emitting element of the display element layer DP-EL.

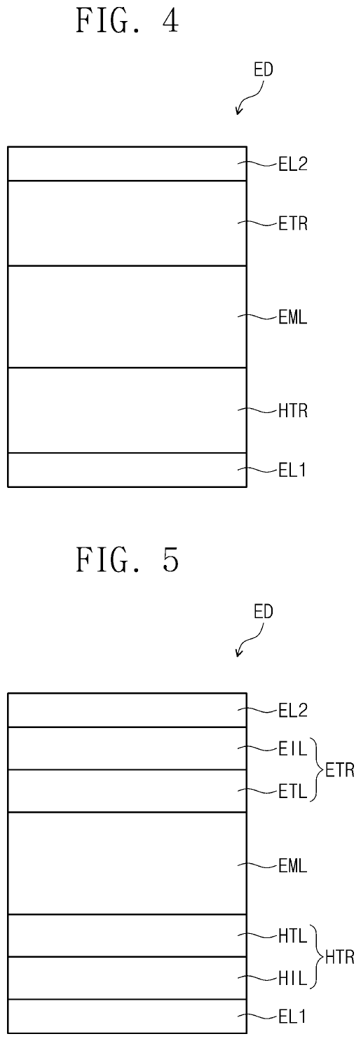

FIGS. 4 to 7 are cross-sectional views of a light emitting element according to an embodiment of the present disclosure.

Referring to FIG. 4, the light emitting element according to an embodiment includes a first electrode EL1, a second electrode EL2 facing the first electrode EL1, and a plurality of functional layers between the first electrode EL1 and the second electrode EL2 and having an emission layer EML.

The plurality of functional layers may include a hole transport region HTR between the first electrode EL1 and the emission layer EML, and an electron transport region ETR between the emission layer EML and the second electrode EL2.

The light emitting element ED according to an embodiment may contain (e.g., include) an antioxidant of an embodiment, which will be further described herein below, in at least one of the hole transport region HTR or the electron transport region ETR. For example, the light emitting element ED of an embodiment may contain an antioxidant according to an embodiment, which will be further described herein below, in the electron transport region ETR and/or the hole transport region HTR which are directly on (e.g., physically contact) the emission layer EML. However, the present disclosure is not limited thereto, and the light emitting element ED of an embodiment may contain an antioxidant according to an embodiment, which will be further described herein below, in the emission layer EML.

In the light emitting element ED according to an embodiment, the first electrode EL1 has conductivity (e.g., electrical conductivity). The first electrode EL1 may be formed of a metal alloy or a conductive compound (e.g., an electrically conductive compound). The first electrode EL1 may be an anode. The first electrode EL1 may be a pixel electrode.

In the light emitting element ED according to an embodiment, the first electrode EL1 may be a reflective electrode. However, the present disclosure is not limited thereto. For example, the first electrode EL1 may be a transmissive electrode or a transflective electrode. When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (e.g., a mixture of Ag and Mg). In one or more embodiments, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the first electrode EL1 may be a multilayer metal film and may have a structure in which metal films of ITO/Ag/ITO are stacked.

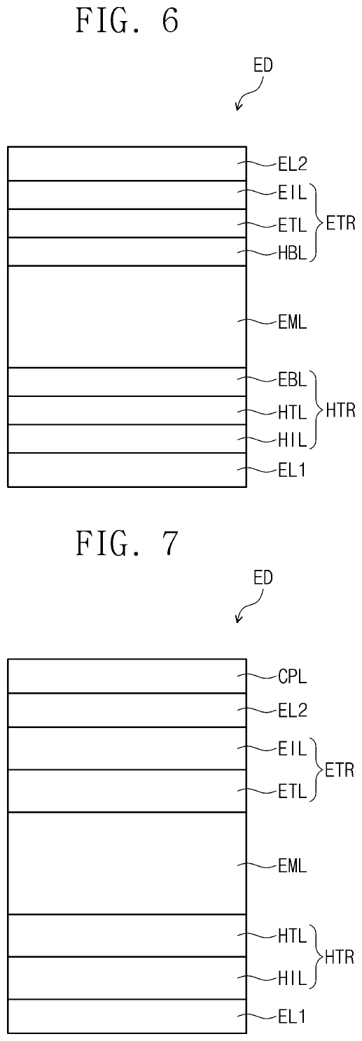

The hole transport region HTR is provided on the first electrode EL1. Referring to FIG. 5, the hole transport region HTR may include a hole injection layer HIL and a hole transport layer HTL. In addition, referring to FIG. 6, the hole transport region HTR may further include an electron blocking layer EBL. The electron blocking layer EBL is a layer that serves to prevent or reduce injection of electrons from the electron transport region ETR to the hole transport region HTR.

In addition, in one or more embodiments, the hole transport region HTR may further include a hole buffer layer. The hole buffer layer may compensate a resonance distance according to wavelengths of light emitted from the emission layer EML, and may thus increase luminous efficiency. Materials which may be included in the hole transport region HTR may be used as materials included in the hole buffer layer.

In an embodiment, the hole transport region HTR may contain an antioxidant according to an embodiment which will be further described herein below. For example, at least one of the hole injection layer HIL and/or the hole transport layer HTL may contain an antioxidant according to an embodiment which will be further described herein below. However, the present disclosure is not limited thereto, and an antioxidant according to an embodiment which will be further described herein below may be included in the electron blocking layer EBL and/or the hole buffer layer.

The hole transport region HTR may have a single layer formed of a single material, a single layer formed of a plurality of different materials, or a multilayer structure having a plurality of layers formed of a plurality of different materials. For example, the hole transport region HTR may have a single-layer structure formed of a plurality of different materials, or a structure in which a hole injection layer HIL/hole transport layer HTL, a hole injection layer HIL/hole transport layer HTL/hole buffer layer, a hole injection layer HIL/hole buffer layer, a hole transport layer HTL/hole buffer layer, or a hole injection layer HIL/hole transport layer HTL/electron blocking layer EBL are stacked in order from the first electrode EL1, but the present disclosure is not limited thereto.

The hole transport region HTR may be formed and provided through an inkjet printing method. However, the present disclosure is not limited thereto, and the hole transport region HTR may be formed using various suitable methods such as a vacuum deposition method, a spin coating method, a cast method, a Langmuir-Blodgett (LB) method, a laser printing method, and/or a laser induced thermal imaging (LITI) method.

The hole injection layer HIL, for example, may include a phthalocyanine compound such as copper phthalocyanine, N,N′-diphenyl-N,N′-bis-[4-(phenyl-m-tolyl-amino)-phenyl]-biphenyl-4,4′-diamine (DNTPD), 4,4′,4″-[tris(3-methylphenyl)phenylamino]triphenylamine] (m-MTDATA), 4,4′,4″-tris(N,N-diphenylamino)triphenylamine (TDATA), 4,4′,4″-tris{N,-(2-naphthyl)-N-phenylamino)-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPD), triphenylamine-containing polyetherketone (TPAPEK), 4-isopropyl-4′-methyldiphenyliodonium tetrakis(pentafluorophenyl)borate, dipyrazino[2,3-f: 2′,3′-h]quinoxaline-2,3,6,7,10,11-hexacarbonitrile (HAT-CN), etc.

The hole transport layer HTL may include any suitable material generally available in the art. For example, the hole transport layer HTL may further include carbazole-based derivatives such as N-phenyl carbazole and polyvinyl carbazole, fluorene-based derivatives, N,N′-bis(3-methylphenyl)-N,N′-diphenyl-[1,1-biphenyl]-4,4′-diamine (TPD), triphenylamine-based derivatives such as 4,4′,4″-tris(N-carbazolyl)triphenylamine (TCTA), N,N′-di(naphthalene-1-yl)-N,N′-diphenyl-benzidine (NPD), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may have a thickness of about 5 nm to about 1,500 nm, for example, about 10 nm to about 500 nm. The hole injection layer HIL, for example, may have a thickness of about 3 nm to about 100 nm, and the hole transport layer HTL may have a thickness of about 3 nm to about 100 nm. for example, the electron blocking layer EBL may have a thickness of about 1 nm to about 100 nm. When the thicknesses of the hole transport region HTR, the hole injection layer HIL, the hole transport layer HTL, and the electron blocking layer EBL satisfy the above-described ranges, suitable or satisfactory hole transport properties may be obtained without a substantial increase in driving voltage.

The emission layer EML is provided on the hole transport region HTR. In the light emitting element ED according to an embodiment, the emission layer EML may include quantum dots.

The quantum dots included in the emission layer EML of an embodiment may be a semiconductor nanocrystal that may be selected from a Group II-VI compound, a Group III-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ and/or In₂Se₃, a ternary compound such as InGaS₃ and/or InGaSe₃, or any combination thereof.

The Group I-III-VI compound may include a ternary compound selected from the group consisting of AgInS, AgInS₂, CuInS, CuInS₂, AgGaS₂, CuGaS₂ CuGaO₂, AgGaO₂, AgAlO₂, and any mixture thereof, and/or a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In one or more embodiments, the Group III-V compound may further include a Group II metal. For example, InZnP, etc. may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In this case, a binary compound, a ternary compound, or a quaternary compound may be present in particles in a uniform (e.g., substantially uniform) concentration distribution, or may be present in the same particles in a partially different concentration distribution. In addition, a core/shell structure in which one quantum dot surrounds another quantum dot may be present. An interface between a core and a shell may have a concentration gradient in which the concentration of an element present in the shell becomes lower along a direction towards the core.

In some embodiments, quantum dots may have the core/shell structure including a core having nano-crystals, and a shell surrounding the core, which are described above. The shell of the quantum dots may serve as a protection layer to prevent or reduce the chemical deformation of the core so as to maintain semiconductor properties, and/or a charging layer to impart electrophoresis properties to the quantum dots. The shell may be a single layer or multiple layers. An interface between the core and the shell may have a concentration gradient in which the concentration of an element present in the shell becomes lower along a direction towards the core. Examples of the shell of quantum dots may be a metal and/or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, COO, Co₃O₄, and/or NiO, and/or a ternary compound such as MgAl₂O₄, CoFe₂O₄, NiFe₂O₄, and/or CoMn₂O₄, but the present disclosure is not limited thereto.

In addition, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the present disclosure is not limited thereto.

Quantum dots may have a full width of half maximum (FWHM) of a light emission wavelength spectrum of about 45 nm or less, about 40 nm or less, or, for example, about 30 nm or less, and color purity and/or color reproducibility may be enhanced in the above ranges. In addition, light emitted through such quantum dots is emitted in all directions (e.g., in substantially all directions), and thus a wide viewing angle may be improved.

In addition, although the form of quantum dots is not particularly limited as long as it is a form generally used or available in the art, and, for example, a quantum dot in the form of spherical, pyramidal, multi-arm, or cubic nanoparticles, nanotubes, nanowires, nanofibers, nanoparticles, etc. may be used.

Quantum dots may control the colors of emitted light according to particle sizes thereof, and thus the quantum dots may emit various suitable colors of light such as blue, red, green, etc.

The emission layer EML may be formed using various suitable methods such as a vacuum deposition method, a spin coating method, a cast method, a Langmuir-Blodgett (LB) method, an inkjet printing method, a laser printing method, and/or a laser induced thermal imaging (LITI) method. In an embodiment, emission layers EL-B, EL-G, and EL-R may be formed by providing a quantum dot composition including quantum dots QD1, QD2, and QD3 of an embodiment through an inkjet printing method.

In the light emitting element ED of an embodiment, the electron transport region ETR is provided on the emission layer EML. Referring to FIG. 5, the electron transport region ETR may include an electron injection layer EIL and an electron transport layer ETL. In addition, referring to FIG. 6, the electron transport region ETR may further include a hole blocking layer HBL. The hole blocking layer HBL is a layer that serves to prevent or reduce injection of electrons from the hole transport region HTR to the electron transport region ETR.

In one or more embodiments, the electron transport region ETR may further include an electron buffer layer. The electron buffer layer may compensate a resonance distance according to wavelengths of light emitted from the emission layer EML, and may thus increase luminous efficiency. Materials which may be included in the electron transport region ETR may be used as materials included in the electron buffer layer.

In an embodiment, the electron transport region ETR may contain an antioxidant according to an embodiment which will be further described herein below. For example, at least one of the electron injection layer EIL and/or the electron transport layer ETL may contain an antioxidant according to an embodiment which will be further described herein below. However, the present disclosure is not limited thereto, and an antioxidant according to an embodiment which will be further described herein below may be included in the hole blocking layer HBL or the electron buffer layer.

The electron transport region ETR may have a single layer formed of a single material, a single layer formed of a plurality of different materials, or a multilayer structure having a plurality of layers formed of a plurality of different materials.

For example, the electron transport region ETR may have a single layer structure of an electron injection layer EIL or an electron transport layer ETL, and may have a single layer structure formed of an electron injection material and an electron transport material. In addition, the electron transport region ETR may have a single layer structure formed of a plurality of different materials, or may have a structure in which an electron transport layer ETL/electron injection layer EIL, or a hole blocking layer HBL/electron transport layer ETL/electron injection layer EIL are stacked in order from the emission layer EML, but is not limited thereto. The electron transport region ETR may have a thickness of, for example, about 20 nm to about 150 nm.

The electron transport region ETR may be formed using various suitable methods such as a vacuum deposition method, a spin coating method, a cast method, a Langmuir-Blodgett (LB) method, an inkjet printing method, a laser printing method, a laser induced thermal imaging (LITI) method, etc. In an embodiment, the electron transport region ETR may be formed and provided through an inkjet printing method.

The electron transport region ETR may further include zinc oxide. Types or kinds of zinc oxide are not particularly limited, but may be, for example, ZnO, ZnMgO, or a combination thereof, and, in addition to Mg, Li and Y may be applied for doping. However, the present disclosure is not limited thereto. For example, zinc oxide may be included in the electron injection layer EIL and/or the hole blocking layer HBL. In one or more embodiments, zinc oxide may be included in at least two of the layers included in the electron transport region ETR.

In addition, as inorganic materials other than zinc oxide, TiO₂, SiO₂, SnO₂, WO₃, Ta₂O₃, BaTiO₃, BaZrO₃, ZrO₂, HfO₂, Al₂O₃, Y₂O₃, ZrSiO₄, etc. may be used, but are not limited thereto.

In an embodiment, when the electron transport layer ETL is directly on (e.g., physically contacts) the emission layer EML as shown in FIG. 5, the electron transport layer ETL may contain zinc oxide and an antioxidant which will be further described herein below. For example, the electron transport region ETR may contain zinc oxide and an antioxidant containing an amine-based compound.

When the electron transport region ETR contains zinc oxide, a trap state may be caused on a nanoparticle surface of zinc oxide due to defects. In this case, the amine-based compound having high binding affinity with zinc may remove the surface defects of nanoparticles to reduce a likelihood or occurrence of the trap state, and ultimately, the stability and luminous efficiency of a light emitting element may increase.

In an embodiment, the electron transport region ETR may include any suitable inorganic material or any suitable organic material generally available in the art.

In an embodiment, the electron transport layer ETL may further include an anthracene-based compound. However, the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, Bis[2-(diphenylphosphino)phenyl]ether oxide (DPEPO), 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), or a mixture thereof.

In an embodiment, the electron injection layer EIL may include a halogenated metal such as LiF, NaCl, CsF, RbCl, and/or RbI, a lanthanide metal such as Yb, a metal oxide such as Li2O and/or BaO, and/or lithium quinolate (LiQ), etc. The electron injection layers EIL may also be formed of a mixture material of an electron transport material and an insulating organo-metal salt. For example, the organo-metal salt may include, for example, metal acetates, metal benzoates, metal acetoacetates, metal acetylacetonates, and/or metal stearates.

In an embodiment, the hole blocking layer HBL may include, for example, at least one of 2,9-dimethyl-4,7-diphenyl-1,10-phenanthroline (BCP) and/or 4,7-diphenyl-1,10-phenanthroline (Bphen), but the present disclosure is not limited thereto.

The second electrode EL2 is provided on the electron transport region ETR. The second electrode EL2 may be a common electrode or a cathode. The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, and/or MgAg). In one or more embodiments, the second electrode EL2 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the second electrode EL2 may include the above-described metal materials, a combination of two or more metal materials selected from the above-described metal materials, and/or oxides of the above-described metal materials.

In one or more embodiments, the second electrode EL2 may be coupled with an auxiliary electrode. When the second electrode EL2 is coupled with the auxiliary electrode, the resistance of the second electrode EL2 may decrease.

Referring to FIG. 7, a capping layer CPL may be further on the second electrode EL2. In an embodiment, the capping layer CPL may contain an antioxidant according to an embodiment which will be further described herein below.

The light emitting element ED according to an embodiment of the present disclosure includes a hole transport region HTR and/or an electron transport region ETR containing an antioxidant. A light emitting element containing quantum dots may stay exposed to moisture and/or oxygen in manufacturing or driving of the light emitting element, thereby causing a high chance of element deterioration. For example, when quantum dots are exposed to oxygen for a long period of time, a defect, which is a trap state, may be formed on a surface. In this case, charges in the element are trapped and quenched, and the luminous efficiency and service life of the element may thus decrease. In embodiments of the present disclosure, an antioxidant is contained in a light emitting element including quantum dots as a light emitting material to prevent or reduce oxidation of quantum dots, and accordingly, the light emitting properties of the light emitting element may be enhanced.

Types or kinds of the antioxidant that may prevent or reduce the oxidation of quantum dots are not particularly limited, but the antioxidant may be, for example, the one containing a phenolic compound and/or an amine-based compound. For example, the antioxidant may contain at least one compound selected from the group consisting of phenolic compounds and amine-based compounds. When the antioxidant contains two or more compounds, the antioxidant may contain a phenolic compound and an amine-based compound, or may contain only a phenolic compound or an amine-based compound.

In an embodiment, the phenolic compound may include at least one selected from among 2,6-di-t-butyl-p-cresol, 2,6-diphenyl-4-octadecyloxyphenol, stearyl (3,5-di-t-butyl-4-hydroxyphenyl)propionate, distearyl(3,5-di-t-butyl-4-hydroxybenzyl) phosphonate, tridecyl 3,5-di-t-butyl-4-hydroxybenzylthioacetate, thiodiethylene bis[(3,5-di-t-butyl-4-hydroxyphenyl)propionate], 4,4′-thiobis(6-t-butyl-m-cresol), 2-octylthio-4,6-di(3,5-di-t-butyl-4-hydroxyphenoxy)-s-triazine, 2,2′-methylenebis(4-methyl-6-t-butylphenol), bis[3,3-bis(4-hydroxy-3-t-butylphenyl)butyrc acid] glycol ester, 4,4′-butylidenebis(2,6-di-t-butylphenol), 4,4′-butylidenebis(6-t-butyl-3-methylphenol), 2,2′-ethylidenebis(4,6-di-t-butylphenol), 1,1,3-tris(2-methyl-4-hydroxy-5-t-butylphenyl)butane, bis[2-tertbutyl-4-methyl-6-(2-hydroxy-3-t-butyl-5-methylbenzyl)phenyl]terephthalate, 1,3,5-trs(2,6-dimethyl-3-hydroxy-4-t-butylbenzyl)isocyanurate, 1,3,5-tris(3,5-di-t-butyl-4-hydroxybenzyl)isocyanurate, 1,3,5-tris(3,5-di-t-butyl-4-hydroxybenzyl)-2,4,6-trimethylbenzene, 1,3,5-tris[(3,5-t-butyl-4-hydroxyphenyl)propionyloxyethyl]isocyanurate, tetrakis[methylene-3-(3′, 5′-di-t-butyl-4′-hydroxyphenyl)propionate]methane, 2-t-butyl-4-methyl-6-(2-acryloyloxy-3-t-butyl-5-methylbenzyl)phenol, 3,9-bis[2-(3-t-butyl-4-hydroxy-5-methylhydrocinnamoyloxy)-1,1-dimethylethyl]-2,4,8,10-tetraoxaspiro[5.5]undecane, triethylene glycol bis [p-(3-t-butyl-4-hydroxy-5-methylphenyl)propionate], and tocopherol, but the present disclosure is not limited thereto.

In an embodiment, the amine-based compound may include at least one selected from among a diphenylamine derivative, a naphthylamine derivative, a 1,2-dihydroquinoline derivative, and a phenylenediamine derivative, but the present disclosure is not limited thereto.

The diphenylamine derivative may include at least one selected from among diphenylamine, N-allyldiphenylamine, and 4-isopropoxydiphenylamine, but the present disclosure is not limited thereto.

The naphthylamine derivative may include at least one selected from among N-phenyl 1-naphthylamine, N-(4-tert-octylphenyl)-1-naphthylamine, and N-phenyl-2-naphthylamine, but the present disclosure is not limited thereto.

The phenylenediamine derivative may include at least one selected from among N,N′-di-isopropyl-p-phenylenediamine, N,N′-di-sec-butyl-p-phenylenediamine, N,N′-bis(1,4-dimethylpentyl)-p-phenylenediamine, N,N′-bis(1-ethyl-3-methylpentyl)-p-phenylenediamine, N,N′-bis(1-methylheptyl)-p-phenylenediamine, N,N′-dicyclohexyl-p-phenylenediamine, N,N′-diphenyl-p-phenylenediamine, N,N′-bis(2-naphthyl)-p-phenylenediamine, N-isopropyl-N′-phenyl-p-phenylenediamine, N-(1,3-dimethylbutyl)-N′-phenyl-p-phenylenediamine, N-(1-methylheptyl)-N′-phenyl-p-phenylenediamine, N-cyclohexyl-N′-phenyl-p-phenylenediamine, 4-(p-toluenesulfamoyl)-diphenylamine, and N,N′-dimethyl-N,N′-di-sec-butyl-p-phenylenediamine, but the present disclosure is not limited thereto.

The 1,2-dihydroquinoline derivative may include at least one selected from among 2,2,4-trimethyl-1,2-dihydroquinoline, 6-ethoxy-2,2,4-trimethyl-1,2-dihydroquinoline, and 6-dodecyl-2,2,4-trimethyl-1,2-dihydroquinoline, but the present disclosure is not limited thereto.

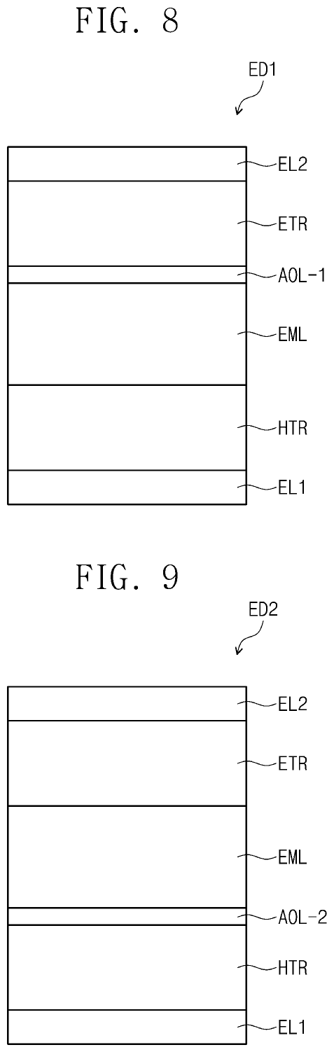

FIGS. 8 to 14 are cross-sectional views illustrating light emitting elements ED1, ED2, ED3, ED4, ED5, ED6, and ED7, respectively, according to another embodiment of the present disclosure. Hereinafter, light emitting elements according to another embodiment of the present disclosure will be described with reference to FIGS. 8 to 14. The same reference numerals are given for the components as described above in FIGS. 4 to 7, and the aforementioned descriptions are not repeated here.

Referring to FIGS. 8 to 14, the light emitting elements ED1, ED2, ED3, ED4, ED5, ED6, and ED7 according to an embodiment may further include respective ones of anti-oxidation layers AOL-1, AOL-2, AOL-3, AOL-4, AOL-6, and AOL-7. The anti-oxidation layers AOL-1, AOL-2, AOL-3, AOL-4, AOL-6, and AOL-7 may contain the above-described antioxidant. The light emitting elements ED1, ED2, ED3, ED4, ED5, ED6, and ED7 according to an embodiment may further include respective ones of the anti-oxidation layers AOL-1, AOL-2, AOL-3, AOL-4, AOL-6, and AOL-7 to have increased luminous efficiency and service life. In embodiments of the present disclosure, the anti-oxidation layers AOL-1, AOL-2, AOL-3, AOL-4, AOL-6, and AOL-7 containing an antioxidant are applied to a light emitting element including quantum dots as a light emitting material to prevent or reduce oxidation of quantum dots and accordingly, the light emitting properties of the light emitting element may be enhanced.

Referring to FIG. 8, the light emitting element ED1 according to an embodiment may further include a first anti-oxidation layer AOL-1. In an embodiment, the first anti-oxidation layer AOL-1 may be between the electron transport region ETR and the emission layer EML. The first anti-oxidation layer AOL-1 may be directly on (e.g., may physically contact) the emission layer EML.

In an embodiment, the electron transport region ETR may contain zinc oxide, and the first anti-oxidation layer AOL-1 may be between the electron transport region ETR and the emission layer EML. For example, the electron transport layer ETL may contain zinc oxide, and the first anti-oxidation layer AOL-1 may be between the electron transport layer ETL and the emission layer EML. In this case, the first anti-oxidation layer AOL-1 may contain an amine-based compound having a high binding affinity with zinc.

When the first anti-oxidation layer AOL-1 contains an amine-based compound, oxidation of quantum dots included in the emission layer may be prevented or reduced and the surface of the electron transport layer ETL containing zinc oxide may be stabilized as well, and accordingly, the luminous efficiency of an element may further increase.

Referring to FIG. 9, the light emitting element ED2 according to an embodiment may further include a second anti-oxidation layer AOL-2. In an embodiment, the second anti-oxidation layer AOL-2 may be between the hole transport region HTR and the emission layer EML. The second anti-oxidation layer AOL-2 may be directly below (e.g., may physically contact) the emission layer EML.

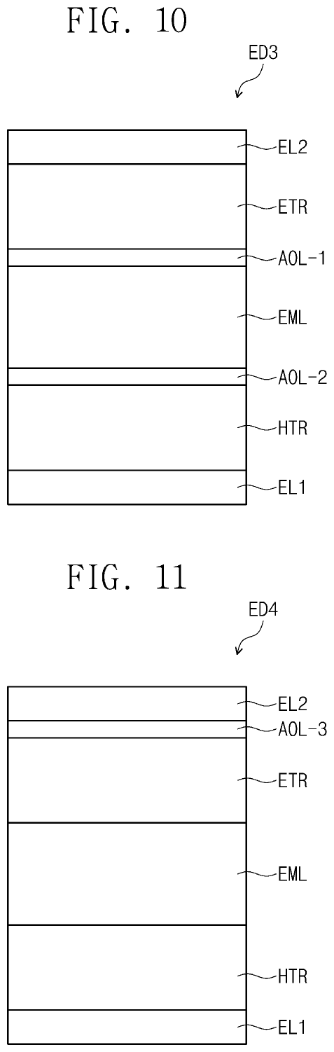

Referring to FIG. 10, the light emitting element ED3 according to an embodiment may further include the first anti-oxidation layer AOL-1 and the second anti-oxidation layer AOL-2. In an embodiment, the first anti-oxidation layer AOL-1 may be between the electron transport region ETR and the emission layer EML. The second anti-oxidation layer AOL-2 may be between the hole transport region HTR and the emission layer EML. The first anti-oxidation layer AOL-1 and the second anti-oxidation layer AOL-2 each may be directly on (e.g., physically contact) the emission layer EML.

Referring to FIG. 11, the light emitting element ED4 according to an embodiment may further include a third anti-oxidation layer AOL-3. In an embodiment, the third anti-oxidation layer AOL-3 may be between the electron transport region ETR and the second electrode EL2.

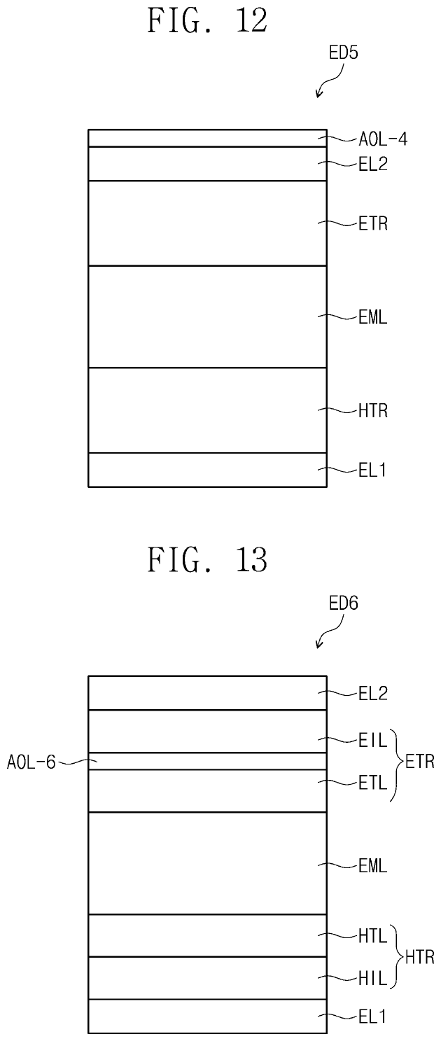

Referring to FIG. 12, the light emitting element ED5 according to an embodiment may further include a fourth anti-oxidation layer AOL-4. In an embodiment, the fourth anti-oxidation layer AOL-4 may be on the second electrode EL2.

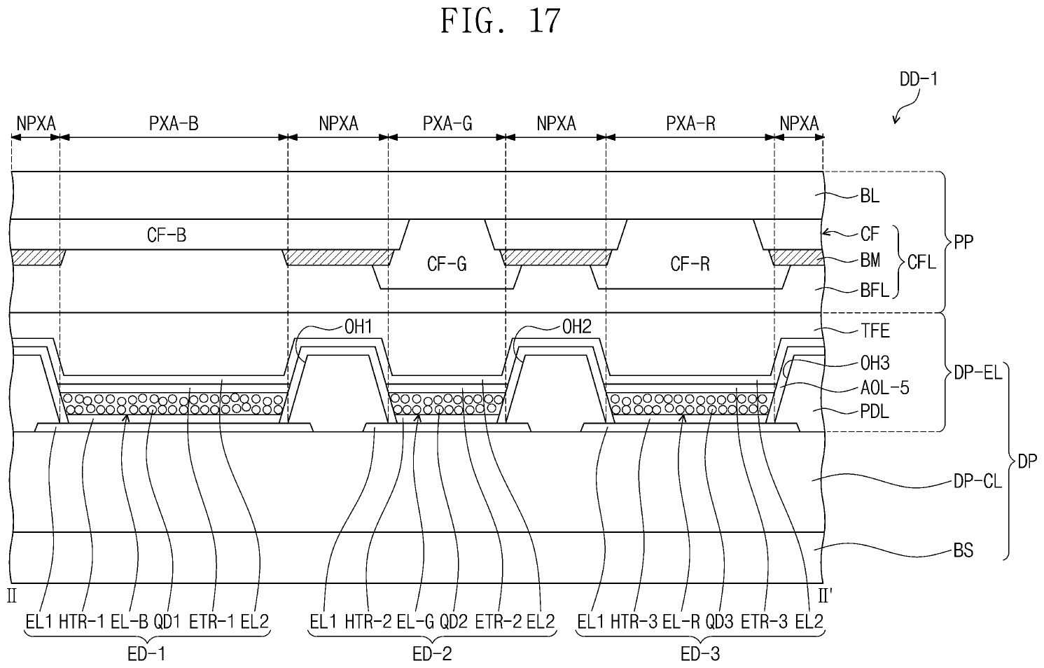

In one or more embodiments, a fifth anti-oxidation layer AOL-5 may be on the pixel defining film PDL (see FIG. 17).

Referring to FIG. 13, the light emitting element ED6 according to an embodiment may further include a sixth anti-oxidation layer AOL-6. In an embodiment, the sixth anti-oxidation layer AOL-6 may be between the electron injection layer EIL and the electron transport layer ETL.

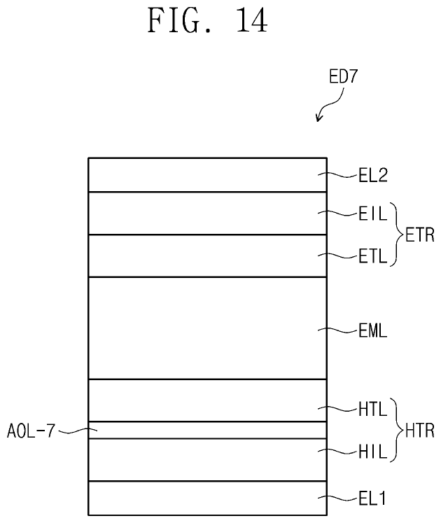

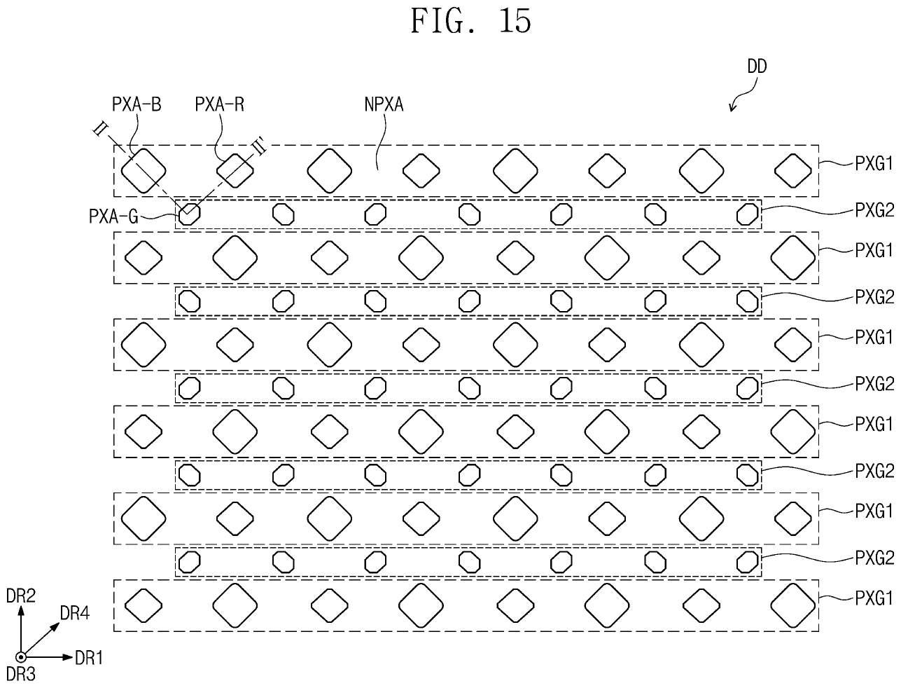

Referring to FIG. 14, the light emitting element ED7 according to an embodiment may further include a seventh anti-oxidation layer AOL-7. In an embodiment, the seventh anti-oxidation layer AOL-7 may be between the hole injection layer HIL and the hole transport layer HTL.

In FIGS. 8, 9, 11 to 14, and 17, the light emitting element is illustrated to include the first to seventh anti-oxidation layers alone, but the present disclosure is not limited thereto, and the light emitting element may include two or more anti-oxidation layers together as desired.

FIG. 15 is a plan view of a display device DD according to an embodiment of the present disclosure. FIG. 16 is a cross-sectional view of a display device DD according to an embodiment. FIG. 16 is a cross-sectional view corresponding to line II-II′ of FIG. 15. In describing the display device DD according to an embodiment illustrated in FIGS. 15 and 16, the same reference numerals are given for the components as described above in FIGS. 1 to 7, and the aforementioned descriptions are not repeated here.

Referring to FIGS. 15 and 16, the display device DD of an embodiment includes a plurality of light emitting elements ED-1, ED-2, and ED-3, and the light emitting elements ED-1, ED-2, and ED-3 respectively include emission layers EL-B, EL-G, and EL-R having quantum dots QD1, QD2, and QD3.

In addition, the display device DD according to an embodiment may include a display panel DP having the plurality of light emitting elements ED-1, ED-2, and ED-3 and an optical member PP on the display panel DP. In one or more embodiments, unlike the one in the drawings, the optical member PP may be omitted in the display device DD of an embodiment.

The display panel DP may include a base substrate BS, a circuit layer DP-CL and a display element layer DP-EL provided on the base substrate BS, and the display element layer DP-EL may include a pixel defining film PDL, light emitting elements ED-1, ED-2 and ED-3 between the pixel defining film PDL, and an encapsulation layer TFE on the light emitting elements ED-1, ED-2 and ED-3.

The display device DD may include a peripheral area NPXA and a plurality of light emitting areas PXA-B, PXA-G, and PXA-R. The light emitting areas PXA-B, PXA-G, and PXA-R each may be an area emitting light generated from respective ones of the light emitting elements ED-1, ED-2, and ED-3. The light emitting areas PXA-B, PXA-G, and PXA-R may be spaced apart from one another on a plane.

The light emitting areas PXA-B, PXA-G, and PXA-R may be divided into a plurality of groups according to colors of light generated from respective ones of the light emitting elements ED-1, ED-2, and ED-3. In the display device DD of an embodiment shown in FIGS. 15 and 16, three light emitting areas PXA-B, PXA-G, and PXA-R which emit blue light, green light, and red light, respectively, are illustrated as an example. For example, the display device DD of an embodiment may include a blue light to emit area PXA-B, a green light to emit area PXA-G, and a red light to emit area PXA-R, which are distinct from one another.

The plurality of light emitting elements ED-1, ED-2, and ED-3 may emit light having different wavelength ranges. For example, in an embodiment, the display device DD may include a first light emitting element ED-1 to emit blue light, a second light emitting element ED-2 to emit green light, and a third light emitting element ED-3 to emit red light. However, the present disclosure is not limited thereto, and the first to third light emitting elements ED-1, ED-2 and ED-3 may emit light in the same wavelength range or emit light in at least one different wavelength range.

For example, the blue light emitting area PXA-B, the green light emitting area PXA-G, and the red light emitting area PXA-R of the display device DD may correspond to the first light emitting element ED-1, the second light emitting element ED-2, and the third light emitting element ED-3, respectively.

A first emission layer EL-B of the first light emitting element ED-1 may include a first quantum dot QD1. A second emission layer EL-G of the second light emitting element ED-2 may include a second quantum dot QD2. A third emission layer EL-R of the third light emitting element ED-3 may include a third quantum dot QD3. The first quantum dot QD1 may emit blue light, which is the first light, the second quantum dot QD2 may emit green light, which is the second light, and the third quantum dot QD3 may emit red light, which is the third light. In an embodiment, the first light may be light having a central wavelength in a wavelength range of about 410 nm to about 480 nm, the second light may be light having a central wavelength in a wavelength range of about 500 nm to about 570 nm, and the third light may be light having a central wavelength in a wavelength range of about 625 nm to about 675 nm.

The quantum dots QD1, QD2, and QD3 may control the colors of emitted light according to particle sizes thereof, and thus the quantum dots QD1, QD2, and QD3 may emit various suitable colors of light such as blue, red, green, etc. The smaller the particle size of the quantum dots QD1, QD2, and QD3 becomes, light in the short wavelength range may be emitted. For example, in the quantum dots QD1, QD2, and QD3 having the same core, the particle size of the quantum dot QD2 to emit green light may be smaller than the particle size of the quantum dot QD3 to emit red light. In addition, in the quantum dots QD1, QD2, and QD3 having the same core, the particle size of the quantum dot QD1 to emit blue light may be smaller than the particle size of the quantum dot QD2 to emit green light. However, the present disclosure is not limited thereto, and even in the quantum dots QD1, QD2, and QD3 having the same core, particle sizes may be adjusted according to forming-materials and thicknesses of a shell. In one or more embodiments, when the quantum dots QD1, QD2, and QD3 emit various suitable colors of light such as blue, red, green, etc., the quantum dots QD1, QD2, and QD3 having different light emitting colors may have different core materials.

In the plurality of light emitting elements ED-1, ED-2, and ED-3 of an embodiment, the emission layers EL-B, EL-G, and EL-R may include a host and a dopant. In an embodiment, the emission layers EL-B, EL-G, and EL-R may include the quantum dots QD1, QD2, and QD3 as a dopant material. In addition, in an embodiment, the emission layers EL-B, EL-G, and EL-R may further include a host material. In one or more embodiments, in the plurality of light emitting elements ED-1, ED-2, and ED-3 of an embodiment, the emission layers EL-B, EL-G, and EL-R may emit fluorescence. For example, the quantum dots QD1, QD2, and QD3 may be used as a fluorescent dopant material.

In one or more embodiments, the first to third quantum dots QD1, QD2, and QD3 each may have a ligand bonded on quantum dot surfaces for improving dispersibility.

In an embodiment, at least one of the emission layers EML-B, EML-G, and EML-R included in the display device DD may further contain the above-described antioxidant. When exposed to an external environment in the manufacturing process or driving of a light emitting element containing quantum dots, moisture and/or oxygen may keep affecting the element, thereby causing a higher chance of element deterioration. In addition, when the quantum dots are exposed to oxygen for a long period of time, surface defects are caused, and accordingly, the luminous efficiency and service life of the element may be reduced. The light emitting elements ED-1, ED-2, and ED-3 according to an embodiment of the present disclosure further contain an antioxidant in the emission layer EML to prevent or reduce oxidation of quantum dots, and ultimately, the luminous properties of the element may be enhanced.

In an embodiment, when the emission layer EML-B, EML-G, and EML-R further contains an antioxidant, the antioxidant may be contained in an amount of about 1 mass % to about 20 mass % with respect to a total weight of quantum dots. However, the present disclosure is not limited thereto.

In the display device DD of an embodiment, as shown in FIGS. 15 and 16, an area of each of the light emitting areas PXA-B, PXA-G and PXA-R may be different in size from one another. In this case, the area may refer to an area when viewed on a plane defined by the first direction DR1 and the second direction DR2.

The light emitting areas PXA-B, PXA-G and PXA-R may have different areas in size according to colors emitted from the emission layers EL-B, EL-G and EL-R of the light emitting elements ED-1, ED-2 and ED-3. For example, referring to FIGS. 15 and 16, the blue light emitting area PXA-B corresponding to the first light emitting element ED-1 emitting blue light may have a largest area, and the green light emitting area PXA-G corresponding to the second light emitting element ED-2 generating green light may have a smallest area in the display device DD of an embodiment. However, the present disclosure is not limited thereto, and the light emitting areas PXA-B, PXA-G and PXA-R may emit light other than blue light, green light and red light, or the light emitting areas PXA-B, PXA-G and PXA-R may have the same size of area, or the light emitting areas PXA-B, PXA-G, and PXA-R may be provided at different area ratios from those shown in FIG. 15.

Each of the light emitting areas PXA-B, PXA-G and PXA-R may be an area separated by the pixel defining film PDL. The peripheral areas NPXA may be an area between neighboring light emitting areas PXA-R, PXA-G, and PXA-B, and may correspond to the pixel defining film PDL. In the present description, each of the light emitting areas PXA-B, PXA-G and PXA-R may correspond to a pixel. The pixel defining film PDL may separate the light emitting elements ED-1, ED-2 and ED-3. The emission layers EL-B, EL-G and EL-R of the light emitting elements ED-1, ED-2 and ED-3 may be in an opening OH defined by the pixel defining film PDL and separated from each other. In an embodiment, the first emission layer EL-B of the first light emitting element ED-1 may be in a first opening OH1, and the second emission layer EL-G of the second light emitting element ED-2 may be in a second opening OH2, and the third emission layer EL-R of the third light emitting element ED-3 may be in a third opening OH3.

The pixel defining film PDL may be formed of a polymer resin. For example, the pixel defining film PDL may be formed to include a polyacrylate-based resin and/or a polyimide-based resin. In addition, the pixel defining film PDL may be formed by further including an inorganic material in addition to the polymer resin. In one or more embodiments, the pixel defining film PDL may be formed including a light absorbing material, and/or may be formed including a black pigment and/or a black dye. The pixel defining film PDL formed including a black pigment and/or a black dye may implement a black pixel defining film. When forming the pixel defining film PDL, carbon black may be used as a black pigment and/or a black dye, but the present disclosure is not limited thereto. In addition, in an embodiment, the pixel defining film PDL may further contain the antioxidant described above.

In addition, the pixel defining film PDL may be formed of an inorganic material. For example, the pixel defining film PDL may be formed to include silicon nitride (SiNx), silicon oxide (SiOx), silicon oxide (SiOxNy), silicon oxynitride (SiNxOy), etc. The pixel defining film PDL may define light emitting areas PXA-B, PXA-G, and PXA-R. The light emitting areas PXA-B, PXA-G, and PXA-R, and the peripheral area NPXA may be separated by the pixel defining film PDL.

The light emitting elements ED-1, ED-2, and ED-3 each may include a first electrode EL1, hole transport regions HTR-1, HTR-2, and HTR-3 on the first electrode EL1, emission layers EL-B, EL-G, and EL-R on the hole transport regions HTR-1, HTR-2, and HTR-3, electron transport regions ETR-1, ETR-2, and ETR-3 on the emission layers EL-B, EL-G, and EL-R, and a second electrode EL2 on the electron transport regions ETR-1, ETR-2, and ETR-3. In one or more embodiments, the light emitting elements ED-1, ED-2, and ED-3 according to an embodiment each may further include at least one of the antioxidant layers according to FIGS. 8 to 14.

The hole transport regions HTR-1, HTR-2, and HTR-3 and the electron transport regions ETR-1, ETR-2, and ETR-3 included in each of the light emitting elements ED-1, ED-2, and ED-3 may be separated by respectively being in the openings OH1, OH2, and OH3 defined in the pixel defining film PDL.

For example, the first hole transport region HTR-1 and the first electron transport region ETR-1 included in the first light emitting element ED-1 may be adjacent to the first emission layer EL-B, and may be patterned and located in the first opening OH1 in which the first emission layer EL-B is located. The second hole transport region HTR-2 and the second electron transport region ETR-2 included in the second light emitting element ED-2 may be adjacent to the second emission layer EL-G, and may be patterned and located in the second opening OH2 in which the second emission layer EL-G is located. The third hole transport region HTR-3 and the third electron transport region ETR-3 included in the third light emitting element ED-3 may be adjacent to the third emission layer EL-R, and may be patterned and located in the third opening OH3 in which the third emission layer EL-R is located. However, the present disclosure is not limited thereto, and the hole transport regions HTR-1, HTR-2, and HTR-3 and the electron transport regions ETR-1, ETR-2, and ETR-3 may be provided as a common layer commonly in pixel areas PXA-B, PXA-G, and PXA-R and the peripheral area NPXA.

In an embodiment, the hole transport regions HTR-1, HTR-2, and HTR-3 and the electron transport regions ETR-1, ETR-2, and ETR-3 each may be provided in the opening OH defined in the pixel defining film PDL through a printing process.

The encapsulation layer TFE may cover the light emitting elements ED-1, ED-2 and ED-3. The encapsulation layer TFE may seal the display element layer DP-EL. The encapsulation layer TFE may be a thin film encapsulation layer. The encapsulation layer TFE may be a single layer or a laminated layer of a plurality of layers. The encapsulation layer TFE includes at least one insulating layer. The encapsulation layer TFE according to an embodiment may include at least one inorganic film (hereinafter, an encapsulation inorganic film). In addition, the encapsulation layer TFE according to an embodiment may include at least one organic film (hereinafter, an encapsulation organic film) and at least one encapsulation inorganic film.

The encapsulation organic film protects the display element layer DP-EL from moisture/oxygen, and the encapsulation organic film protects the display element layer DP-EL from foreign substances such as dust particles. The encapsulation inorganic film may include a silicon nitride layer, a silicon oxy nitride layer, a silicon oxide layer, a titanium oxide layer, an aluminum oxide layer, etc., but is not particularly limited thereto. The encapsulation organic layer may include an acrylic-based compound, an epoxy-based compound, etc. The encapsulation organic layer may include a photopolymerizable compound, and is not particularly limited.

The encapsulation layer TFE may be on the second electrode EL2, and may fill the opening OH.

In the display device DD of an embodiment illustrated in FIG. 16, although the thicknesses of the emission layers EL-B, EL-G, and EL-R of the first to third light emitting elements ED-1, ED-2, and ED-3 are illustrated to be similar to one another, the embodiment is not limited thereto. For example, in an embodiment, the thicknesses of the emission layers EL-B, EL-G, and EL-R of the first to third light emitting elements ED-1, ED-2, and ED-3 may be different from one another. In addition, thicknesses of the hole transport regions HTR-1, HTR-2, and HTR-3 and electron transport regions ETR-1 and ETR-2 and ETR-3 of the first to third light emitting elements ED-1, ED-2, and ED-3 may also be different from each other.

Referring to FIG. 15, the blue light emitting areas PXA-B and the red light emitting areas PXA-R may be alternately arranged in the first direction DR1 to form a first group PXG1. The green light emitting areas PXA-G may be arranged in the first direction DR1 to form a second group PXG2.

The first group PXG1 and the second group PXG2 may be spaced apart in the second direction DR2. Each of the first group PXG1 and the second group PXG2 may be provided in plural. The first groups PXG1 and the second groups PXG2 may be alternately arranged in the second direction DR2.

One green light emitting area PXA-G may be spaced apart from one blue light emitting area PXA-B or one red light emitting area PXA-R in the fourth direction DR4. The fourth direction DR4 may be a direction between the first direction DR1 and the second direction DR2.

The arrangement structure of the light emitting areas PXA-B, PXA-G and PXA-R shown in FIG. 15 may have a PENTILE® arrangement structure (e.g., an RGBG matrix, RGBG structure, or RGBG matrix structure). PENTILE® is a duly registered trademark of Samsung Display Co., Ltd. However, the arrangement structure of the light emitting areas PXA-B, PXA-G and PXA-R in the display device DD according to an embodiment is not limited to the arrangement structure shown in FIG. 15. For example, in an embodiment, the light emitting areas PXA-B, PXA-G and PXA-R may have a stripe structure in which the blue light emitting area PXA-B, the green light emitting area PXA-G, and the red light emitting area PXA-R may be alternately arranged along the first direction DR1.

Referring to FIGS. 3 and 16, the display device DD of an embodiment may further include an optical member PP. The optical member PP may block or reduce transmission of external light to the display panel DP from the outside the display device DD. The optical member PP may block or reduce transmission of a portion of external light. The optical member PP may perform an anti-reflection function minimizing or reducing reflection due to external light.

In an embodiment illustrated in FIG. 16, the optical member PP may include a color filter layer CFL. For example, the display device DD of an embodiment may further include the color filter layer CFL on the light emitting elements ED-1, ED-2, and ED-3 of the display panel DP.

In the display device DD of an embodiment, the optical member PP may include a base layer BL and a color filter layer CFL.

The base layer BL may be a member that provides a base surface on which the color filter layer CFL is located. The base layer BL may be a glass substrate, a metal substrate, a plastic substrate, etc. However, the present disclosure is not limited thereto, and the base layer BL may be an inorganic layer, an organic layer, or a composite material layer including an inorganic material and an organic material.

The color filter layer CFL may include a light blocking unit BM and a color filter CF. The color filter may include a plurality of filters CF-B, CF-G, and CF-R. In one or more embodiments, the color filter layer CFL may include a first filter CF-B to transmit a first color light, a second filter CF-G to transmit a second color light, and a third filter CF-R to transmit a third color light. For example, the first filter CF-B may be a blue filter, the second filter CF-G may be a green filter, and the third filter CF-R may be a red filter.

Each of the filters CF-B, CF-G, and CF-R may include a polymer photosensitive resin and a pigment and/or a dye. The first filter CF-B may include a blue pigment and/or a blue dye, the second filter CF-G may include a green pigment and/or a green dye, and the third filter CF-R may include a red pigment and/or a red dye.

The present disclosure, however, is not limited thereto, and the first filter CF-B may not include a pigment and/or a dye. The first filter CF-B may include a polymer photosensitive resin, but not include a pigment and/or a dye. The first filter CF-B may be transparent. The first filter CF-B may be formed of a transparent photosensitive resin.

The light blocking unit BM may be a black matrix. The light blocking unit BM may be formed including an organic light blocking material and/or an inorganic light blocking material, both including a black pigment and/or a black dye. The light blocking unit BM may prevent or reduce light leakage, and separate boundaries between the adjacent filters CF-B, CF-G, and CF-R.

The color filter layer CFL may further include a buffer layer BFL. For example, the buffer layer BFL may be a protection layer protecting the filters CF-B, CF-G, and CF-R. The buffer layer BFL may be an inorganic material layer including at least one inorganic material selected from among silicon nitride, silicon oxide, and silicon oxynitride. The buffer layer BFL may be formed of a single layer or a plurality of layers.

In an embodiment shown in FIG. 16, the first color filter CF-B of the color filter layer CFL is illustrated to overlap the second filter CF-G and the third filter CF-R, but the present disclosure is not limited thereto. For example, the first to third filters CF-B, CF-G and CF-R may be separated by the light blocking unit BM and may not overlap one another. In an embodiment, the first to third filters CF-B, CF-G and CF-R may respectively correspond to the blue light emitting area PXA-B, green light emitting area PXA-G, and red light emitting area PXA-R.

Unlike shown in FIG. 16 and the like, the display device DD of an embodiment may include a polarizing layer as the optical member PP instead of the color filter layer CFL. The polarizing layer may block or reduce transmission of external light to the display panel DP from the outside. The polarizing layer may block or reduce transmission of a portion of external light.

In addition, the polarizing layer may reduce the reflection of external light by the display panel DP. For example, the polarizing layer may function to block or reduce the reflection of light provided from the outside the display device DD that is incident to the display panel DP and would have otherwise exited the display panel DP. The polarizing layer may be a circular polarizer having an anti-reflection function or the polarizing layer may include a linear polarizer and a λ/4 phase retarder. In one or more embodiments, the polarizing layer may be on the base layer BL to be exposed or the polarizing layer may be below the base layer BL.

In one or more embodiments, the light emitting elements ED-1, ED-2, and ED-3 may have an inverted structure. For example, the plurality of light emitting elements ED-1, ED-2, and ED-3 each may include a first electrode EL1, electron transport regions ETR-1, ETR-2, and ETR-3 on the first electrode EL1, emission layers EL-B, EL-G, and EL-R on the electron transport regions ETR-1, ETR-2, and ETR-3, hole transport regions HTR-1, HTR-2, and HTR-3 on the emission layers EL-B, EL-G, and EL-R, and a second electrode EL2 on the hole transport regions HTR-1, HTR-2, and HTR-3.

FIG. 17 is a cross-sectional view of a display device DD-1 according to an embodiment of the present disclosure. In describing the display device DD-1 according to an embodiment illustrated in FIG. 17, the same reference numerals are given for the components as described above in FIG. 16, and the aforementioned descriptions are not repeated here.

The display device DD-1 of an embodiment illustrated in FIG. 17 may include a display panel DP having a plurality of light emitting elements ED-1, ED-2, and ED-3 and an optical member PP. The same descriptions as in FIG. 16 may be applied to a base substrate BS, a circuit layer DP-CL, and an optical member PP included in the display device DD-1 illustrated in FIG. 17.

The display device DD-1 of an embodiment illustrated in FIG. 17 has a difference in the display element layer DP-EL from the display device DD of an embodiment illustrated in FIG. 16. The display element layer DP-EL included in the display device DD-1 of FIG. 17 may further include a fifth anti-oxidation layer AOL-5.

In one or more embodiments, the display element layer DP-EL may include the pixel defining film PDL, the fifth anti-oxidation layer AOL-5 on the pixel defining film PDL, and the light emitting elements ED-1, ED-2, and ED-3 between the pixel defining film PDL, and the encapsulation layer TFE on the light emitting elements ED-1, ED-2, and ED-3.

The fifth anti-oxidation layer AOL-5 may be formed on an upper surface of the pixel defining film PDL to prevent or reduce oxidation of quantum dots. The fifth anti-oxidation layer AOL-5 may be on the pixel defining film PDL in which a plurality of openings OH1, OH2, and OH3 are defined, and at least a portion of the fifth anti-oxidation layer AOL-5 may contact (e.g., physically contact) the second electrode EL2.

The fifth anti-oxidation layer AOL-5 may contain the antioxidant of the above-described embodiment. Accordingly, the fifth anti-oxidation layer AOL-5 may prevent or reduce oxidation of quantum dots due to an external environment. For example, the fifth anti-oxidation layer AOL-5 may serve to prevent or reduce occurrence of surface defects of quantum dots that may be caused by oxygen and/or moisture during a patterning process of a light emitting element and/or during driving of an element.

In the display device DD-1 according to an embodiment of the present disclosure, as described in FIGS. 8 and 14, an anti-oxidation layer may be between other functional layers included in the light emitting elements ED-1, ED-2, and ED-3, in addition to the upper surface of the pixel defining film PDL. For example, an anti-oxidation layer may be on at least one of between electron transport regions ETR-1, ETR-2, and ETR-3 and emission layers EML-B, EML-G, and EML-R, between emission layers EML-B, EML-G, and EML-R and hole transport regions HTR-1, HTR-2, and HTR-3, between emission layers EML-B, EML-G, and EML-R and the second electrode EL2, and/or on an upper surface of the second electrode EL2.

However, the present disclosure is not limited thereto, and the electron transport regions ETR-1, ETR-2 and ETR-3 in the light emitting elements ED-1, ED-2, and ED-3 may further include an electron injection layer and an electron transport layer, and an anti-oxidation layer may be further between the electron injection layer and the electron transport layer. In addition, the hole transport regions HTR-1, HTR-2 and HTR-3 in the light emitting elements ED-1, ED-2, and ED-3 may further include a hole injection layer and a hole transport layer, and an anti-oxidation layer may be further between the hole injection layer and the hole transport layer.

Hereinafter, embodiments of the present disclosure will be described in more detail with reference to a specific Example and Comparative Example. Examples shown below are illustrated only for the understanding of the present disclosure, and the scope of the present disclosure is not limited thereto.

### EXAMPLE OF PREPARING ELEMENTS

In order to evaluate properties of light emitting elements according to the Example and Comparative Example, the light emitting elements of an embodiment were prepared through a method described below. As an antioxidant, 2,6-di-t-butyl-p-cresol was added to an electron transport layer to prepare a light emitting element of Example 1. A light emitting element of Comparative Example 1 was prepared in substantially the same manner as in Example 1, except that the electron transport layer did not contain an antioxidant.

### Example 1

An ITO glass substrate (25×25 mm) was ultrasonically washed sequentially using distilled water and isopropanol, and UV ozone-cleaned for 30 minutes. PEDOT-PSS (clevios AI4083) was dripped (deposited) on the cleaned substrate using inkjet printing, and the resultant was baked at 110° C. for 30 minutes to form a hole injection layer having a thickness of about 200 nm. A polyvinylcarbazole solution in which polyvinylcarbazole was dissolved in chlorobenzene in an amount of about 1.1 wt % was prepared, and the solution was dripped (deposited) on the hole injection layer using inkjet printing, and then, the resultant was baked at 150° C. for 30 minutes in a glove box under a nitrogen atmosphere to form a hole transport layer having a thickness of about 40 nm.

The prepared QD was dripped (deposited) on the hole transport layer using inkjet printing, and then the resultant was baked at 110° C. for 30 minutes in a glove box under a nitrogen atmosphere to form an emission layer having a thickness of 20 nm. Subsequently, a solution in which ZnO nanoparticles were dispersed in ethanol in an amount of about 2.0 wt % was prepared, and the solution was dripped (deposited) on the emission layer using inkjet printing, and then the resultant was baked at 110° C. for 30 minutes in a glove box under a nitrogen atmosphere to from an electron transport layer having a thickness of about 60 nm. On the electron transport layer, aluminum (Al) was deposited to have a thickness of about 100 nm through thermal evaporation to form a cathode.

### Comparative Example 1

From Example 1 above, a light emitting element was prepared in substantially the same manner as in Example 1, except that the antioxidant 2,6-di-t-butyl-p-cresol was not used.

### Evaluation of Light Emitting Element Properties

In order to evaluate properties of light emitting elements according to the Example and Comparative Example, luminous efficiency, quantum efficiency, and driving voltage were measured. Table 1 shows the luminous efficiency (cd/A) and driving voltage (V) at a current density of 10 mA/cm² and a luminance of 520 cd/m² for the prepared light emitting elements.

TABLE 1

| | Luminous efficiency | Voltage |
|---|---|---|
| | (cd/A) | (V) |
| Example 1 | 7.1 | 3.1 |
| Comparative | 6.7 | 3.2 |
| Example 1 | | |

Referring to the results of Table 1, it can be seen that Example 1 containing an antioxidant had a relatively higher luminous efficiency and a lower driving voltage than Comparative Example 1 without containing an antioxidant.

The light emitting element according to an embodiment of the present disclosure contains an antioxidant, and may thus achieve high luminous efficiency and low driving voltage.

A light emitting element and a display device according to an embodiment of the present disclosure contains an antioxidant, and may thus exhibit increased luminous efficiency.

A display device according to an embodiment of the present disclosure includes an anti-oxidation layer containing an antioxidant, and may thus exhibit increased luminous efficiency.

Although the embodiments of the present disclosure have been described above with reference to the accompanying drawings, those skilled in the art to which the present disclosure pertains may implement the present disclosure in other specific forms without changing the technical idea or essential features thereof. Therefore, it should be understood that the embodiments described above are example in all respects and not restrictive.

What is claimed is:

1. A light emitting element comprising:
a first electrode;
a hole transport region on the first electrode;
an emission layer on the hole transport region and comprising quantum dots;
an electron transport region on the emission layer; and
a second electrode on the electron transport region,
wherein at least one selected from the hole transport region and the electron transport region comprises an antioxidant.

2. The light emitting element of claim 1, wherein the antioxidant comprises a phenolic compound and/or an amine-based compound.

3. The light emitting element of claim 1, wherein the electron transport region comprises:
an electron transport layer on the emission layer; and
an electron injection layer on the electron transport layer, and
at least one selected from the electron transport layer and the electron injection layer comprises the antioxidant.

4. The light emitting element of claim 3, wherein:
the electron transport layer comprises zinc oxide and the antioxidant; and
the electron transport layer is directly on the emission layer.

5. The light emitting element of claim 1, wherein the hole transport region comprises:
a hole injection layer on the first electrode; and
a hole transport layer on the hole injection layer, and
at least one selected from the hole injection layer and the hole transport layer comprises the antioxidant.

6. The light emitting element of claim 1, wherein the emission layer comprises the antioxidant,
the antioxidant being included in an amount of about 0.1 mass % to about 10 mass % with respect to a total weight of the quantum dots.

7. The light emitting element of claim 1, further comprising a first anti-oxidation layer between the electron transport region and the emission layer and comprising the antioxidant.

8. The light emitting element of claim 1, further comprising a second anti-oxidation layer between the hole transport region and the emission layer and comprising the antioxidant.

9. A light emitting element comprising:
a first electrode;
a hole transport region on the first electrode;
an emission layer on the hole transport region and comprising quantum dots;
an electron transport region on the emission layer;
a second electrode on the electron transport region; and
an anti-oxidation layer on the hole transport region,
wherein the anti-oxidation layer comprises an antioxidant.

10. The light emitting element of claim 9, wherein:
the electron transport region comprises zinc oxide;
the anti-oxidation layer is between the electron transport region and the emission layer; and
the antioxidant comprises an amine-based compound.

11. The light emitting element of claim 9, wherein the anti-oxidation layer is between the hole transport region and the emission layer.

12. The light emitting element of claim 9, wherein the anti-oxidation layer is between the electron transport region and the second electrode.

13. The light emitting element of claim 9, wherein the anti-oxidation layer is on the second electrode.

14. A display device comprising:
a display panel comprising a base layer and a plurality of light emitting elements on the base layer; and
an optical member on the display panel,
wherein the plurality of light emitting elements each comprise:
a first electrode;
a hole transport region on the first electrode;
an emission layer on the hole transport region and comprising quantum dots;
an electron transport region on the emission layer; and
a second electrode on the electron transport region,
wherein at least one selected from the hole transport region selected from the electron transport region comprises an antioxidant.

15. The display device of claim 14, wherein the plurality of light emitting elements comprise:
a first light emitting element comprising a first quantum dot to emit a first light;
a second light emitting element comprising a second quantum dot to emit a second light having a longer wavelength than the first light; and
a third light emitting element comprising a third quantum dot to emit a third light having a longer wavelength than the first light and the second light.

16. The display device of claim 15, wherein the optical member comprises a color filter layer,
the color filter layer comprising:
a first filter to transmit the first light;
a second filter to transmit the second light; and
a third filter to transmit the third light.

17. The display device of claim 14, further comprising:
a first anti-oxidation layer between the electron transport region and the emission layer and comprising the antioxidant; and/or
a second anti-oxidation layer between the hole transport region and the emission layer and comprising the antioxidant.

18. The display device of claim 17, wherein:
the electron transport region comprises zinc oxide; and
the antioxidant comprises an amine-based compound.

19. The display device of claim 14, wherein the display panel further comprises:
a pixel defining film on the base layer and having a plurality of openings respectively corresponding to the plurality of light emitting elements defined therein; and
a fifth anti-oxidation layer on the pixel defining film and comprising the antioxidant.

20. The display device of claim 14, wherein the display panel further comprises a pixel defining film on the base layer and having a plurality of openings respectively corresponding to the plurality of light emitting elements defined therein, and
the pixel defining film comprises the antioxidant.
